(19) United States
(12) Patent Application Publication
(10) Pub. No.: US 2006/0035173 A1
(43) Pub. Date: Feb. 16, 2006

(54) Patterning thin metal films by dry reactive ion etching

(76) Inventors: Mark Davidson, Florahome, FL (US); Jean Tokarz, Hawthorne, FL (US); Jonathan Gorrell, Saint Thomas, VI (US)

Correspondence Address: DAVIDSON BERQUIST JACKSON & GOWDEY LLP, 4300 WILSON BLVD., 7TH FLOOR, ARLINGTON, VA, 22203, US

(21) Appl. No.: 10/917,511

(22) Filed: Aug. 13, 2004

(51) Int. Cl. G03F 7/36

(52) U.S. Cl. 430/318

(57) ABSTRACT

We describe a new method for etching patterns in silver, copper, or gold, or other plate metal thin films. A pattern of a hard mask is placed onto the surface of the thin film, followed by a step of reactive ion etching using a plasma formed using a gas feed of some combination of some amounts of methane (CH₄) and hydrogen (H₂), and some or no amount of Argon (Ar). The areas of silver, copper or gold not covered by the hard mask are etched while the hard mask protects those areas that will form the raised portions of thin film in the final structure.

### FIELD OF THE INVENTION

This relates to the field of metal etching, and particularly to patterning thin metal films by dry reactive ion etching.

We describe a new method for etching patterns in silver, copper, or gold, or other plate metal thin films. In some of the embodiments, the method consists of putting a pattern of a hard mask onto the surface of the thin film, followed by reactive ion etching using a plasma formed using a gas feed of some combination of some amounts of methane (CH₄) and hydrogen (H₂), and some or no amount of Argon (Ar). The areas of silver, copper or gold not covered by the hard mask are etched while the hard mask protects those areas that will form the raised portions of thin film in the final structure.

One potential use for patterning silver thin films is in the production of integrated circuits. Typically, aluminum is used as the primary conductor for interconnects and integrated circuits. However, the conductivity of aluminum is relatively poor compared to copper or silver. In addition, aluminum is subject to a phenomenon known as electro-migration, which causes failure of interconnects after long-term use. Higher molecular weight metals such as silver are less susceptible to electro-migration. The higher conductivity of silver and copper can also lead to higher efficiency, lower energy loss devices.

In recent years, integrated circuits have been produced using copper interconnects. However, the copper cannot be patterned using known conventional dry etched techniques. Typically, that copper has to be patterned using the so-called “Damascene” process. That process is a multi-step process, which involves chemical mechanical polishing. This is a highly complicated and difficult to control process in the production environment. It is advantageous to develop an improved dry etched process for silver, which is compatible with conventional dry etch process tools such as inductively coupled plasma (ICP) space or electron cyclotron resonance (ECR) high density plasma reactors.

There have been several efforts to develop dry etch processes for silver based on halogen chemistries (e.g. Chlorine (Cl₂), tetrafluoromethane (CF₄), sulfur hexafluoride (SF₆)). While halogen chemistries work well for silicon-based thin films, it has been repeatedly found that silver halides are not volatile enough to be easily removed from the surface during the etch process. This results in residues of silver halides forming on the surface, which then must be removed by some post-processing technique. Alternatively, it has been proposed that halides chemistries can be used when the substrate is held at elevated temperatures (˜200° C.). At elevated temperature, the vapor pressure of the formed halides is high enough that they are removed from the surface during the reactive ion etch. In many cases, high temperatures can lead to problems of diffusion and grain growth of the materials and layers on the device. This problem is exacerbated by the very small size of the features in modern integrated circuits and devices.

In U.S. Pat. No. 5,157,000, Elkind et al. teach a method to dry etch openings in the surface of a wafer made of Group II and Group VI elements. Elkind et al describe a second processing step after the dry etch, namely a wet etching step to smooth and expand the openings. Elkind et al do not describe an acceptable way to eliminate that second processing step.

In U.S. Pat. No. 5,705,443, Stauf et al. teach a method of plasma assisted dry etching to remove material from a metal containing layer. No patterns are formed in the surface.

In U.S. Pat. No. 6,080,529, Ye et al. teach a method of etching patterns into a conductive surface. The conductive surface is coated with a high-temperature masking material, which is imaged and processed to produce a patterned mask in any suitable standard method. The mask pattern is transferred to the conductive surface using an anisotropic etch process. After the etch, Ye et al describe a second processing step to remove the residual masking material is then removed with a plasma etching step. Ye et al do not an acceptable way to eliminate the second processing step.

Alford et al. in an article published in Microelectronic Engineering 55 (2001) 383-388 studied the etching and patterning of silver thin films. Alford et al. used pure CF₄, which creates a silver fluoride (AgF) species that must be removed in a secondary processing step.

K. B. Jung et al. in the article entitled “Patterning of Cu, Co, Fe, and Ag for Magnetic Nanostructures,” (J. Vac. Sci. Tech. A, 15(3), May/June 1997, pp 1780-1784) disclose a method of etching silver samples, using a gas mixture of CH₄/H₂/Ar. The researchers present evidence of patterns etched in copper, but did not pattern the silver surfaces. In contrast, a presently described method produces intricate patterns of nanostructures that provide the opportunity to etch in a single step (or more, only if desired) and in a way that is compatible with industrial microprocessor production. Further, the etch chemistry disclosed by Jung et al. still requires a method for producing patterns, such as is described in the presently preferred embodiment.

Nguyen et al, “Novel Technique to Pattern Silver Using CF4 and CF4/O2 Glow Discharges,” J. Vac. Sci. Technol. B 19, No. 1, January/February 2001, 1071-1023, used CF₄ RIE followed by a secondary rinse to do the etching. Nguyen et al also looked at Cl₂/O₂ chemistry for etching. With this chemistry, they believe that Cl—O—Ag compounds form then are sputtered away. The resulting surfaces tended to be rough as the Cl₂ corroded the silver. The researchers did etch lines into the silver, on the order of 10 microns in width.

Zeng et. al., “Processing and encapsulation of silver patterns by using reactive ion etch and ammonia anneal,” Materials Chemistry and Physics 66 (2000) 77-82 etched silver films using an oxygen plasma, which caused the silver to oxidize and flake unless encapsulated in an atmosphere of flowing ammonia gas. This processing method is incompatible with current semiconductor processing practice.

We have discovered new methods of dry etching the surface of, for example, silver films. The methods can be designed to avoid any secondary wet etch, although the invention does not prevent such a wet etch (or other secondary processing step) if the artisan optionally wishes for other reasons to incorporate one or more. We have discovered, for example, that when etching silver in a dry etch reactor using a mixture of methane and hydrogen, and in some instances also argon to generate a combination of reaction with the silver surface, volatile hydrides and/or hydrocarbons that are formed will volatilize spontaneously or undergo sputter assisted removal. Such a method is compatible with micro-electronic processing.

The dry etching method yields smooth, sub-micron sized features and, for the first time, can selectively do so with or without a preliminary and/or secondary etch process and remain in compatibility with industrial microprocessor production.

One example mixture includes any fraction of methane (1-99%), hydrogen (1-99%), and argon (0-99%) in a plasma etcher.

In an example embodiment, we describe the use of a hard mask resistant to etching by methane, hydrogen and argon.

We also describe a method of etching silver films that is compatible with micro-electronic processing.

Methods that we describe can be used to etch smooth, fine patterns into silver films in a single etching step, with no secondary etching step required. Although the invention does not necessarily preclude secondary or preliminary etchings, the methods described can provide new ways to eliminate secondary and preliminary etchings, if so desired.

Our described methods also can be used to produce smooth fine features of any size or form factor with other metals.

### BRIEF DESCRIPTION OF THE DRAWINGS

FIG. 1A is a schematic drawing of a substrate coated with a thin metallic film and a layer of masking material.

FIG. 1B is a schematic drawing showing the pattern formed in the masking material.

FIG. 2 is a scanning electron microscope (SEM) photograph of typical etch profile of structure and etched using the preferred embodiment.

FIG. 3 is a set of graphs that show the effect of RF power, pressure, and substrate temperature on etch rate of silver for a gas composition consisting of 11.5 sccm H₂, 8.5 sccm CH₄, and 10 sccm Ar.

FIG. 4 is a series of graphs illustrating the optimal conditions for the preferred embodiment.

### DESCRIPTION OF ONE OR MORE PREFERRED EMBODIMENTS

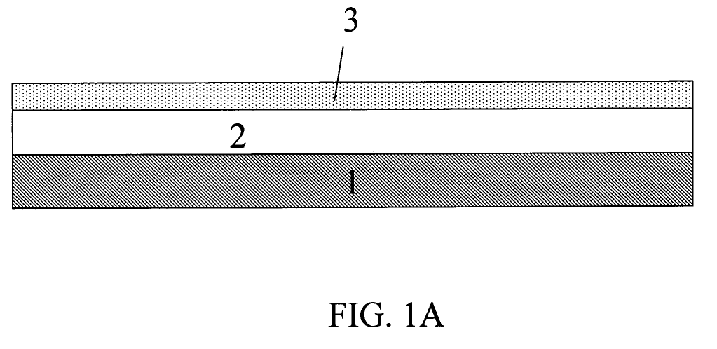

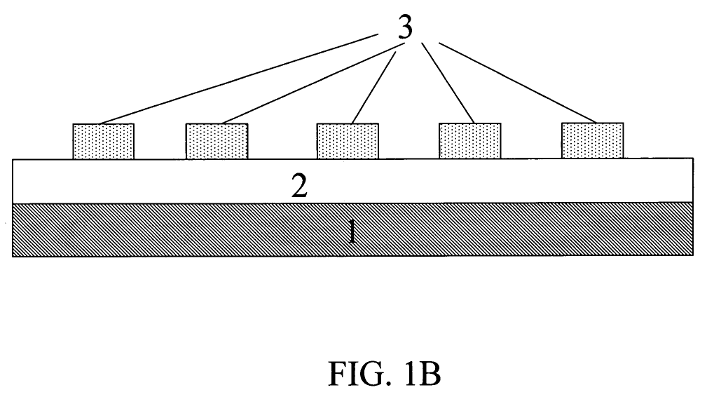

In FIG. 1A a substrate 1 is shown coated with a metallic layer 2. In the preferred embodiment, the substrate, 1, is comprised of silicon, and can be smooth and suitable for coating with a metal layer. In the preferred embodiment, the layer 2 is a thin film of silver, however, thin layers of copper or gold are also suitable.

A hard mask layer 3 is shown deposited on top of the metal layer 2. In the preferred embodiment, a chromium layer is used as the etch resist mask. There is no requirement that the masking material be chromium. The masking material could be any material that is capable of withstanding the plasma chemistry long enough to protect the silver in the areas where no etching is desired. These may include, but are not limited to, a metal layer, a ceramic layer such as silicon nitride or silicon oxide, or a soft material such as a polymer or photoresist.

Alternatively, poly-methyl methacrylate (PMMA) is used as the etch mask when the Ag film is in the 100 to 200 nm range of thickness. In this case, the selectivity (ratio of resist etch rate to Ag etch rate) is around 1:1, but the PMMA can be made thicker than the Ag. This allows the Ag to be etched through the full thickness prior to the resist being etched through.

In addition, other photoresists that are more resistant to etching in this chemistry can be used to etch thicker layers of Ag. However, many of these resists are reactive towards the Ag. In this case, a thin layer of carbon a few nanometers in thickness is evaporated over the layer of silver to act as a diffusion barrier and stop the reaction of the photoresist with the Ag film. Once the pattern is written into the resist mask, the carbon layer can be easily removed from the silver with, for example, a short oxygen plasma or ozone treatment.

In FIG. 1B, the hard mask layer 3 is shown patterned on top of the silver layer. In the preferred embodiment, the patterning is done using the “lift-off” method, familiar to those skilled in the art. Alternatively, any method of patterning that results in the desired feature size may be used to pattern the hard mask layer 3.

After the mask is patterned, the sample is placed into a reactor. The reactor is preferably an ECR reactor, although it could be an ICP, straight RF plasma, a DC “glow discharge” plasma, or other suitable reactor. It could also be any other source capable of generating reactive atoms and molecules from the source gas, is such as a laser. In the preferred embodiment a mixture of methane, hydrogen, and argon, flows into the reactor.

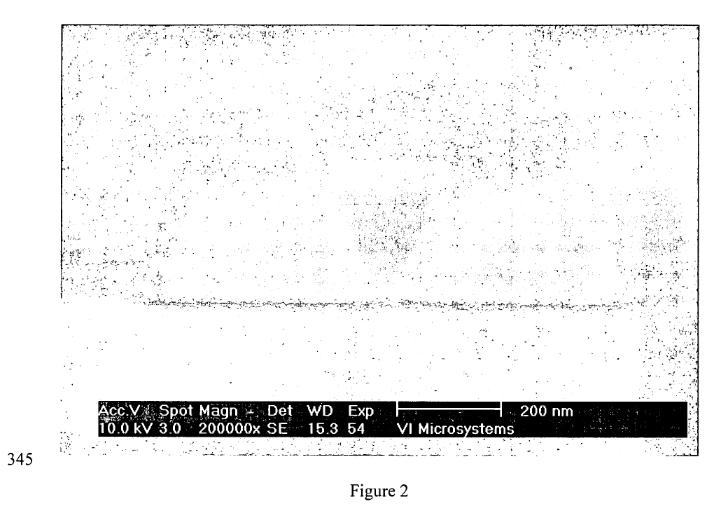

FIG. 2 is a scanning electron microscope micrograph that shows a silver film etched using the preferred embodiment of the invention. The patterned features are 400 nm at their base and 200 nm high and are spaced less than 100 nm apart. The features are smooth and can be made devoid of the masking layer.

It is well known that the optimal reactor conditions such as power density, temperature, pressure and gas composition depend strongly upon the type of reactor, the size and shape of the features being etched. Consideration must also be given to the balance between effects such as desirable etch rates and mask selectivity, minimum feature size, and etch profile. These factors are typically assigned some weight based on their importance, and a full optimization of the reactor conditions is performed.

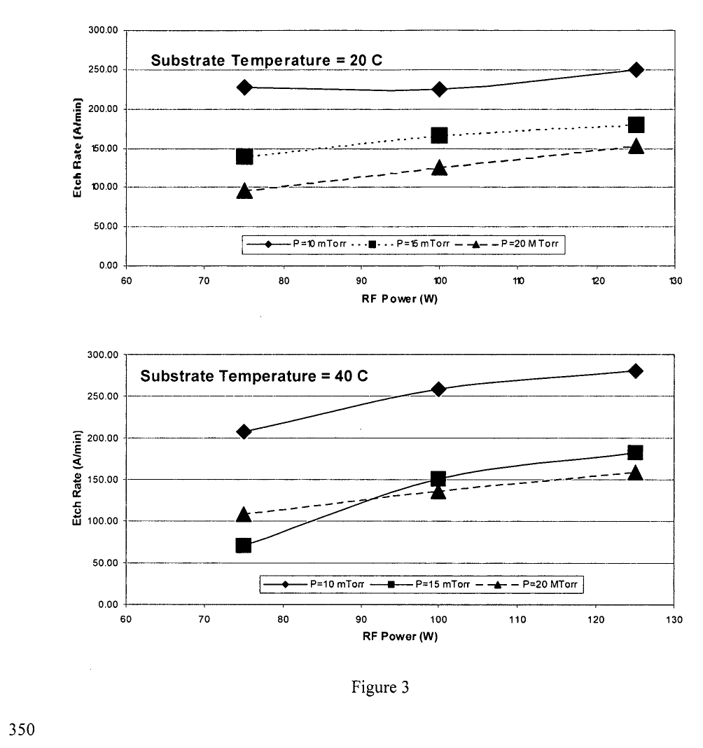

The results optimization of the etch conditions, used in the preferred embodiment, are shown in FIG. 3. The etch conditions were optimized on a Plasmatherm model 770SLR ECR etch tool equipped with numerous source gases, including methane, hydrogen, Argon and Helium. The optimization was performed on structures with nominal feature sizes on the order of 0.5 um etched to a nominal depth of 0.5 um. Initial experiments showed that good etch rates (˜25 nm/min) were obtained with the reactor pressure of 10 mTorr, RF power of 100 W, substrate temperature of 20 C, 400 W ECR microwave power, and flow rates of 11.5, 8.5, and 10 SCCM (standard cubic centimeters per minute) of hydrogen, methane and Argon, respectively. These conditions were found to be optimal for this particular rectangular geometry features, using Cr as an etch mask on the Plasmatherm 770.

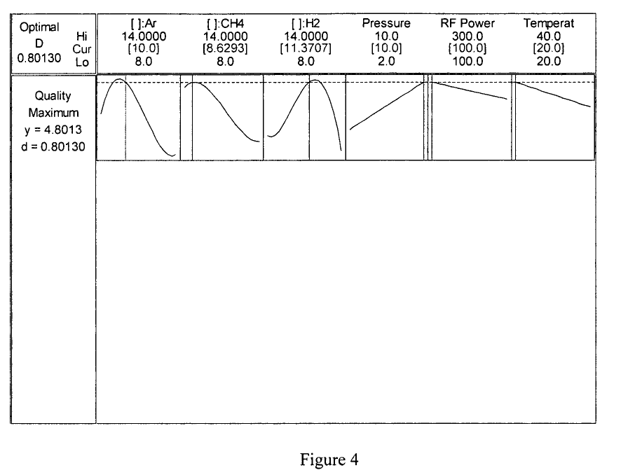

The same basic chemistry consisting of mixtures of methane, hydrogen, and argon may be found to provide satisfactory results at different compositions and specific reactor conditions, depending upon the desired balance between critical dimensions, etch rates, and mask selectivity. Typically, the ideal condition is determined by a statistical design of experiments (DOE) to make a model, which is then used to determine the optimal condition. Some results and trends from one such DOE are shown in FIG. 4.

In the plots of FIG. 4, the quality of each etch condition is quantified by a qualitative factor which ranged from 1 to 5, representing poor to good etches. This factor is a subjective factor determined by inspection of the etched test patterns and takes into account the critical dimension, mask selectivity, etch rate, particle generation etc. The plots in FIG. 4 show the variation of the model with each of the parameters shown, with the other parameters held constant at their optimal conditions. This optimal etch condition produced small, cleanly etched features with sidewall angles of 75-80 degrees.

As expected, the overall trend is that as the pressure goes up, the etch rates go down. This is consistent with a mechanism involving the formation of volatile species bound to the surface, followed by sputter-assisted desorption.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method for pattering a thin metal film layer deposited, comprising:
depositing a mask layer on said thin metal film layer,
defining a pattern in said mask layer; and
transferring said pattern from said mask layer to said thin metal film layer in a single step dry etch process,
wherein said dry etch process occurs at 20° C. to 50° C.

2. The method of claim 1 wherein said thin metal film layer is comprised of silver.

3. The method of claim 1 wherein said mask layer is comprised of chromium.

4. The method of claim 1 wherein said mask layer is comprised of iron, gold or platinum.

5. The method of claim 1 wherein said mask layer is comprised of a ceramic material.

6. The method of claim 1 wherein said mask layer is comprised of silicon oxide or silicon nitride.

7. The method of claim 1 wherein the gas composition used in said single step etch process comprises a mixture of any fraction of methane, hydrogen, and argon in the etch reaction.

8. The method of claim 1 wherein said dry etch process occurs at 20° C. to 40° C.

9. A method for patterning a thin metal film comprising:
depositing a reaction barrier layer on said thin metal film;
depositing a layer of photoresist on said reaction barrier layer;
defining a pattern in said layer of photoresist; and
transferring said pattern from said layer of photoresist to said thin metal film by a single step dry etch process.
wherein said single step dry etch process occurs at 20° C. to 50° C.

10. The method of claim 9 wherein a gas composition used in said single step dry etch process comprises a mixture of any fraction of methane, hydrogen, and argon in the etch reaction.

11. The method of claim 9 wherein said reaction barrier layer is comprised of carbon.

12. The method of claim 9 wherein said reaction barrier layer is comprised of SiOₓ.

13. The method of claim 9 wherein said reaction barrier layer is comprised of a ceramic.

14. The method of claim 9 wherein said thin metal film is comprised of silver.

15. The method of claim 9 wherein said single step dry etch process occurs at 20° C. to 40° C.

16. A method for patterning a thin metal film comprising:
depositing a mask layer comprising chromium on said thin metal film;
defining a pattern in said mask layer; and
transferring said pattern to said thin metal film by a single step dry etch process,
wherein said single step dry etch process occurs at 20° C. to 50° C.

17. The method of claim 16 wherein a gas composition used in said single step dry etch process comprises a mixture of any fraction of methane, hydrogen, and argon in the etch reaction.

18. The method of claim 16 wherein said single step dry etch process occurs at 20° C. to 40° C.

19. A method for patterning a thin metal film comprising:
depositing a carbon layer on said thin metal film;
depositing a layer of photoresist on said carbon layer;
defining a pattern in said layer of photoresist; and
transferring said pattern to said thin metal film by a single step dry etch process.
wherein said single step dry etch process occurs at 20° C. to 50° C.

20. The method of claim 19 wherein a gas composition used in said single step dry etch process comprises a mixture of any fraction of methane, hydrogen, and argon in the etch reaction.

21. The method of claim 19 wherein said single step dry etch process occurs at 20° C. to 40° C.

22. A method for patterning a thin metal film comprising:
depositing a SiOₓ layer on said thin metal film;
depositing a layer of photoresist on said SiOₓ layer;
defining a pattern in said layer of photoresist; and
transferring said pattern to said thin metal film by means of a single dry etch process,
wherein said single step dry etch process occurs at 20° C. to 50° C.

23. The method of claim 22 wherein a gas composition used in said dry etch process comprises a mixture of any fraction of methane, hydrogen, and argon in the etch reaction.

24. The method of claim 22 wherein said single step dry etch process occurs at 20° C. to 40° C.

25. A method, comprising:
providing a metal film of at least one metal from the group consisting of silver, copper or gold;
depositing an etch mask on the metal film;
defining a pattern in the etch mask; and
exposing the pattern, etch mask and at least portions of the metal film to a mixture of an effective amount of methane and hydrogen in a plasma etcher,
wherein said single step dry etch process occurs at 20° C. to 50° C.

26. A method according to claim 25, wherein
the mixture in the step of exposing includes an effective amount of methane, hydrogen, and argon.
